(19) United States
(12) Patent Application Publication
(10) Pub. No.: US 2026/0169053 A1
(43) Pub. Date: Jun. 18, 2026

(54) METHOD AND SYSTEM FOR DEGRADATION PREDICTION OF A POWER DEVICE ASSEMBLY

(71) Applicant: RISE RESEARCH INSTITUTES OF SWEDEN AB, Boras (SE)

(72) Inventor: Andreas LÖVBERG, St. Peters (AU)

(73) Assignee: RISE RESEARCH INSTITUTES OF SWEDEN AB, Boras (SE)

(21) Appl. No.: 19/125,944

(22) PCT Filed: Oct. 30, 2023
(86) PCT No.: PCT/EP2023/080250

§ 371 Date: Apr. 30, 2025

(30) Foreign Application Priority Data
Nov. 1, 2022 (EP) 22204911.6

(51) Int. Cl. G01R 31/26; G01R 31/27; G01R 31/42

(52) U.S. Cl. CPC G01R 31/2642; G01R 31/2601; G01R 31/27; G01R 31/42

(57) ABSTRACT

The present invention related to the field of degradation and/or failure prediction, and more specifically to the field of prediction of degradation and/or failure of power devices and assemblies comprising power devices. The method according to the invention comprises a pre-phase creating a data model for determining the degradation level of a power device; a calibration phase wherein the data model is used to provide a set of power devices with known degradation levels which are used to create a database of behavior signatures of power device assemblies; and a run-time phase determining the remaining lifetime of an installed power device assembly in use. A system suitable for executing the method is provided.

### FIELD OF THE INVENTION

The present disclosure is generally related to the field of degradation and/or failure prediction, and more specifically to the field of prediction of degradation and/or failure of power devices and assemblies comprising power devices.

### BACKGROUND OF THE INVENTION

Power devices, or power electronics, are utilized in a plethora of technological fields such as, for example, household electronics, transportation systems and space applications. Regardless of the technological field, it is of importance that the power electronics are able to provide stable and reliable electrical power. Additionally, the increased electrification of many technological fields, such as for example automotive and transportation, further increases the need for precisely controllable power devices. However, the power device will eventually break down, which will greatly reduce the precision and/or the reliability of the power device, thereby requiring that the power device is either replaced or repaired. Further, if the power device breaks down unexpectedly it may cause great cost and/or harm (a worst case scenario could be a power device of a train breaking down mid-journey, thereby potentially losing control of the train). Therefore, it is of great interest to provide reliable and predictive maintenance of power devices.

One of the main challenges in reliability and predictive maintenance is relating the results from conventional accelerated life testing of power devices to real-world applications where failures develop over a much longer period of time. In addition to this, the accelerated life testing is usually performed with a constant loading scheme, such as by using a constant thermal cycling, while a real-world application often entails variable loading, which may entail both environmental and operating conditions.

“Overview of Real-Time Lifetime Prediction and Extension for SiC Power Converter”s, Ni Ze et. al., IEEE TRA1'ISACTIONS ON FOWER ELECTRONICS, VOL. 35. NO. 8, August 2020 and US 2019/324432 provides extensive and comprehensive overviews of lifetime predictions of power devices. Still there is a clear need for methods and systems that can be utilized during use of a power device, typical a power devices being part of a power device assembly in for example an inverter of an electrically powered vehicle.

### SUMMARY OF THE INVENTION

An object of the present invention is to provide a method and a system which may mitigate, alleviate or eliminate one or more of the above-identified deficiencies in the art.

This is achieved by the method as defined in claim 1, and the system as defined in claim 13.

According to one aspect of the invention a system for determining the remaining lifetime of a power device assembly in use is provided. The system comprises:
a first part comprising a power devices, a power cycling unit arranged to provide a drive cycle to the power device and monitoring unit arranged to monitor an indicative parameter relating to the power device being subjected to a set of power cycles provided by the power cycling unit,
a second part comprising a power device assembly, the comprising of one or more power devices, an assembly drive unit arranged to provide a life like drive cycle to the power device assembly and an assembly monitoring unit arranged to monitor and record behavior data of the power device assembly 140 during the drive cycle; and
a third part comprising an installed power device assembly in use in an application, and a run-time monitoring unit connected to the installed power device assembly and arranged to monitor and record behavior data of the power device assembly during use.

According to one aspect of the invention a method of determining the remaining lifetime of a power device assembly in use is provided. The method preferably executed using the above-described system and wherein the power device assembly comprises at least one power device of a specific type of power devices.

The method comprises a pre-phase with a main step of:
creating a data model relating a measured indicative parameter to a degradation level of a power device by performing accelerated life testing until failure on a first set of the specific power devices,
   a calibration phase comprising the main steps of:
providing a second set of power devices with individual degradation levels by performing accelerated life testing under the same conditions as in the pre-phase with different duration of the accelerated life testing for the individual test power devices, and using the data model to ascribe a degradation level to each individual test power device;
providing a set of a plurality of test power device assemblies, each comprising at least one test power device from the second set of test power devices, and subjecting each of the test power device assemblies to life-like testing and recording a behavior of each of the test power device assemblies during the life-like testing and associating the recorded behavior as a behavior signature specific to the degradation level of the test power device or devices comprised in each test power device assembly; and
creating a database of behavior signatures with associated degradation levels,
   and a run-time phase comprising the main step of:
determining the remaining lifetime of an installed power device assembly, the installed power device assembly corresponding to the test power device assemblies, by monitoring the behavior of the power device assembly and comparing the result with the behavior signatures of the database.

According to one embodiment of the invention the pre-phase comprises the steps of:
providing a first set of a plurality of test power devices of the specific type of power device;
subjecting each of the test power devices in the first set of test power devices to power cycling and for each power device recording an indication parameter until failure for the power device; and
creating a data model using the recorded indication parameter for each test power device, the data model relating the indication parameter to an expected remaining life of the type of power device.

According to one embodiment of the invention the calibration phase comprises the steps of:
providing a second set of a plurality of test power devices of the specific type of power device;
subjecting each of the test power devices in the second set of test power devices to power cycling and recording the indication parameter and providing different duration of the power cycling for the individual test power devices;
ascribing a degradation value to each of the test power devices in the second set of test power devices using the data model, (wherein the degradation value is an indication of the remaining lifetime of the power device);
providing a set of a plurality of test power device assemblies, each comprising at least one test power device from the second set of test power devices; and
subjecting each of the test power device assemblies to a predetermined life-like drive cycle and recording the behavior of each of the test power device assemblies during the drive cycle, and associating the recorded behavior as a behavior signature specific to the degradation value of the test power device comprised in each test power device assembly, and
creating a database of behavior signatures with associated degradation values.

According to one embodiment of the invention the run-time-phase comprises:
monitoring an installed power device assembly during use and recording the behavior of the power device assembly during a predetermined time period;
determining the remaining lifetime of the installed power device assembly by using the database and comparing the recorded behavior of the power device assembly with the stored behavior signatures.

According to one embodiment of the invention the indication parameter is a measure of the on-state voltage of the individual power device. According to one embodiment the indication parameter is a measure of the temperature of the individual power device. The indication parameter may also be a combination of measure of the on-state voltage and a measure of the temperature of the individual power device.

According to one embodiment of the invention the data model is a machine learning model and the step of creating the data model comprises training the machine learning model. The machine learning model may utilize one of, or a combination of: multilayer-perceptron, recurrent neural network, convolutional neural network and transformers.

According to one embodiment of the invention the step of determining the remaining lifetime comprises finding the best match between the recorded behavior of the power device assembly with the stored behavior signatures comprises using an Euclidean distance, a Fréchet distance or a pattern matching technique.

According to one embodiment of the invention the step of subjecting the test power device assemblies to the predetermined life-like drive cycle has a duration in time that is equal to the predetermined time period of the step of monitoring the power device assembly during use. The predetermined time period may be less than 5 seconds.

According to one embodiment of the invention degradation level of a power device and/or a power device assembly indicates a level of damage present in one or more connection interface(s) of a power device comprised in the power device assembly. The one or more connection interface(s) of the power device may comprise one or more wire bond(s) of the power device.

According to one embodiment of the invention system further comprises control means and analyzing means arrange to:

During a pre-phase control the first part of the system to perform the steps of:
creating a data model relating a measured indicative parameter to a degradation level of a power device by performing accelerated life testing until failure on a first set of the specific power devices,
providing a second set of power devices with individual degradation levels by performing accelerated life testing under the same conditions as in the pre-phase with different duration of the accelerated life testing for the individual test power devices, and using the data model to ascribe a degradation level to each individual test power device;

During a calibration phase control the second part of the system (100b) to perform the main steps of:
subjecting each of the test power device assemblies in a set of a plurality of test power device assemblies to a predetermined life-like drive cycle, wherein each test power device assemblies comprises at least one test power device from the second set of test power devices and recording the behavior of each of the test power device assemblies during the drive cycle, and associating the recorded behavior as a behavior signature specific to the degradation value of the test power device comprised in each test power device assembly, and
creating a database of behavior signatures with associated degradation levels, and

During a run-time phase control the third part of the system to perform the steps of:
determining the remaining lifetime of an installed power device assembly, the installed power device assembly corresponding to the test power device assemblies, by monitoring the behavior of the power device assembly and comparing the result with the behavior signatures of the database.

According to one embodiment of the invention the control means and analyzing means are arrange to:
during the pre-phase control the first part of the system to perform the steps of:
   subjecting each of the test power devices in the first set of test power devices to power cycling and for each power device recording an indication parameter until failure for the power device; and
   creating a data model using the recorded indication parameter for each test power device, the data model relating the indication parameter to an expected remaining life of the type of power device,
   subjecting each of the test power devices in the second set of test power devices to power cycling and recording the indication parameter and providing different duration of the power cycling for the individual test power devices;
   ascribing a degradation value to each of the test power devices in the second set of test power devices using the data model, (wherein the degradation value is an indication of the remaining lifetime of the power device),
during the calibration phase control the second part of the system to perform the steps of:
   subjecting each of the test power device assemblies to a predetermined life-like drive cycle and recording the behavior of each of the test power device assemblies during the drive cycle, and associating the recorded behavior as a behavior signature specific to the degradation value of the test power device comprised in each test power device assembly, and creating a database of behavior signatures with associated degradation values, and
during the run-time phase control the third part of the system to perform the steps of:
   monitoring an installed power device assembly during use and recording the behavior of the power device assembly during a predetermined time period;
      determining the remaining lifetime of the installed power device assembly by using the database and comparing the recorded behavior of the power device assembly with the stored behavior signatures.

Thanks to the invention it is possible to create a plurality of power devices each having a predicted level of degradation (i.e. being categorized with a predicted level of degradation) allows for exposing each of said degraded power devices to a predetermined drive cycle (which may be configured to simulate a real-world application). Thereby, one is able to observe, and record, how a power device which is degraded to a certain level would behave in a real-world application, or “similar-to-real-world” application. These recordings can then be labeled with the level of degradation of their respective degraded power device. The labeled recordings thereby form a library, or database, of recorded behavior data with the predicted level of degradation of the degraded power devices. Thereby, the library (or database) comprises a plurality of level of degradation labeled recordings which have been created using realistic drive cycles. Thus, the created library allows for an improved prediction of degradation and/or failure of power devices in comparison to the art. Improved could both in the sense of a better prediction but also in the sense that the run-time phase of the prediction can be made much faster than prior art methods.

One advantage of the invention is the flexibility in using the method and system with a wide range of power devices and/or power device assemblies.

Other objectives, features and advantages of the enclosed embodiments will be apparent from the following detailed disclosure, from the attached dependent claims as well as from the drawings.

### BRIEF DESCRIPTION OF THE DRAWINGS

In the following, the invention will be described in more detail, by way of example only, with regard to non-limiting embodiments thereof, reference being made to the accompanying drawings.

FIGS. 1a-c schematically illustrate a) a first part, b) a second part, and c) a third part of the system for prediction of degradation of a power device assembly according to the invention;

FIG. 2 is a flowchart illustrating the method for prediction of degradation of a power device assembly according to the invention;

FIGS. 3a-d schematically illustrate the output at different stages of the method according to the invention and relating to a) the first part, b) the second part, and c-d) a third part of the system for prediction of degradation of a power device assembly according to the invention;

FIG. 4a-d schematically shows a method according to an exemplifying embodiment of the present disclosure.

### DETAILED DESCRIPTION

Terms such as “top”, “bottom”, upper“, lower”, “below”, “above” etc are used merely with reference to the geometry of the embodiment of the invention shown in the drawings and/or during normal operation of the device/devices and are not intended to limit the invention in any manner.

An established method of investigating the lifetime of an electronic or electrical device or component is to subject the device, hereinafter referred to as a power device, to power cycling. The objective of power cycling, or drive cycle, may be to generate targeted stress situations in the power device under strongly accelerated conditions which can lead to signs of wear and degradation on the power device. The power cycling may exert targeted stress on the chip-near interconnections, such as wire-bonds, die-attach and/or top-side contacting of the power device to a die. The stress may be caused by the heat generated within the power device during the power cycling which may induce tensions and/or tears caused by the different expansion coefficients of the different materials of the power device. Degradation processes include, but are not limited to: delamination, crack formation, cracks and intermetallic growth, and electromigration. Degradation of a power device may increase resistance of the power device, which may consequently increase an operating voltage of the power device. Consequently, data recorded during a power cycling may relate to, but not limited to, a voltage, a resistance, a current and/or another electrical measurement of the power device. Further, the data may relate to a temperature of the power device measured and recorded during and/or after a power cycle.

The power cycling may be performed in accordance with the ECPE Guideline AQG 324, or any other guideline provided by the ECPE (i.e. the European Center for Power Electronics e.V.). More specifically, the power cycling may be conducted as per IEC 60749-34:2011. However, it is to be understood that the present disclosure is not limited to conducting power cycling in accordance with the mentioned standard tests, and that they should rather be understood as a guideline or inspiration for the skilled person.

A round of power cycling may comprise having the power device connected to a power source which switches the power device to an on-state and then to an off-state. The parameters of the power cycle is preferably chosen with regards to the type of power device to be investigated. For example, the power cycling may involve subjecting a power device to a series of electrical pulses, such that the power device is repeatedly turned on for a first predetermined time and then turned off for a second predetermined time. The first and second predetermined times may be equal or different. For example, the first and/or the second predetermined times may be equal to 10, 5, 3, or 1 second(s).

The power device may be a semiconductor power device, or semiconductors, for example but not limited to, insulated-gate bipolar transistors, IGBTs, bipolar junctions transistors, BJTs, metal-oxide-semiconductor field-effect transistors, MOSFETs, junction-gate field-effect transistors, JFETs, thyristors and/or diodes. A typically measure to characterize a semiconductor device is the on-state voltage, a voltage drop across the semiconductor. For a MOSFET, the on-state voltage may be understood as the gate voltage of the MOSFET. Further, the gate voltage may, for a MOSFET, be understood as a drain-source voltage. For a BJT, the on-state voltage may be understood a base-emitter voltage.

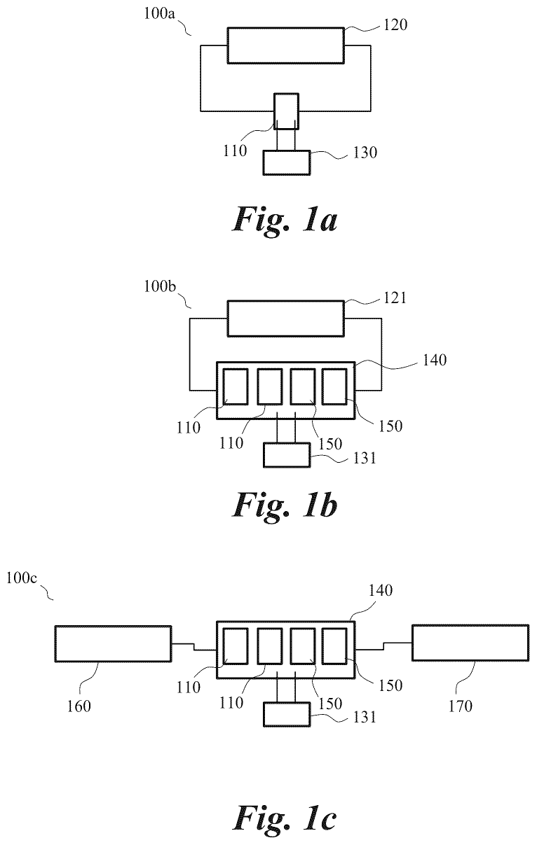

According to the invention a system and a method for prediction of degradation of a power device assembly comprising one or more individual power devices are provided. FIG. 1a-c schematically illustrates the system comprising three different parts which are utilized during different stages of the method.

The first part of the system 100a, schematically illustrated in FIG. 1a is used to characterize individual power devices 110 and comprises a power cycling unit 120 arranged to, during a testing procedure, provide a drive cycle to a power device 110. The power cycling unit 120 is typically arranged to provide a number of predefined power cycles that may vary in power and duration. A monitoring unit 130 is arranged to monitor an indicative parameter relating to the power device 110 being subjected to a set of power cycles by the power cycling unit 120. The power cycling unit 120 and the monitoring unit 130 as such are well known in the art and are commercially available and/or comprises of commercially available parts. The first part of the system 100a may be arranged to simultaneously test a plurality of individual power devices 110. In such a set-up the power cycling unit 120 and/or the monitoring unit 130 may be duplicated.

The second part of the system 100b, schematically illustrated in FIG. 1b, is used to characterize a power device assembly 140, the assembly 140 comprising of one or more power device 110 and additional components 150, such as capacitors, resistors, diodes and thyristors. The second part of the system 100b further comprises an assembly drive unit 121 arranged to, during a testing procedure, provide a drive cycle to the power device assembly 140. The assembly drive unit 121 is typically and preferably arranged to provide a predetermined life-like drive cycle to the power device assembly 140. The life-like drive cycle will be further discussed below in describing the method according to the invention. An assembly monitoring unit 131 is connected to the power device assembly 140 and is arranged to monitor and record behavior data of the power device assembly 140 during the drive cycle. Behavior data can relate to the output of the power device assembly 140 or a physical measurement made purely for characterizing the power device assembly 140. Behavior data may for example be a voltage, a resistance, a current and/or another electrical measurement of the power device. Further, the behavior data may be a temperature of the power device assembly 140 measured and recorded during and/or after a drive cycle. Temperature may be measured contactless, which is included in the term “connected to”, although not connected as in electrically connected. The power device assembly 140 may be any type of device based on or including power devices as described above. Typical power device assemblies include, but is not limited to inverters, rectifiers and converters. Power device assemblies may be found in everything from household electrical and electronic appliances to electrical vehicles and switchgears. A power device assembly 140 may comprise of only one power device 400, which may be referred to as a “sample power device”. The assembly drive unit 121 and the assembly monitoring unit 131 as such are well known in the art and are commercially available and/or comprises of commercially available parts.

The third part of the system 100c, schematically illustrated in FIG. 1c, is used to characterize an installed power device assembly 140 in use in an application. “Installed” should here be understood as the power device assembly 140 being used in its intended application, typically being part of a larger piece of equipment, for example in a drive line of an electrical vehicle. For illustrative purposes only, the installed power device assembly 140 is placed in between and in connection with for example a power source 160 and a power consuming device 170, for example an electrical engine. A run-time monitoring unit 132 is connected to the installed power device assembly 140. The run-time monitoring unit 132 is arranged to generate the same type of behavior data as the assembly monitoring unit 131 of the second part of the system 100b. Preferably, the run-time monitoring unit 132 is essentially identical to the assembly monitoring unit 131. Essentially identical should here be understood that the different units are arranged to produce the same output as response to the same input, although the actual design may differ since the assembly monitoring unit 131 is typically a test laboratory equipment and the run-time monitoring unit 132 may be a device to be used in the field or a device that is permanently mounted in for example a vehicle. The run-time monitoring unit 132 as such is well known in the art and are commercially available and/or comprises of commercially available parts.

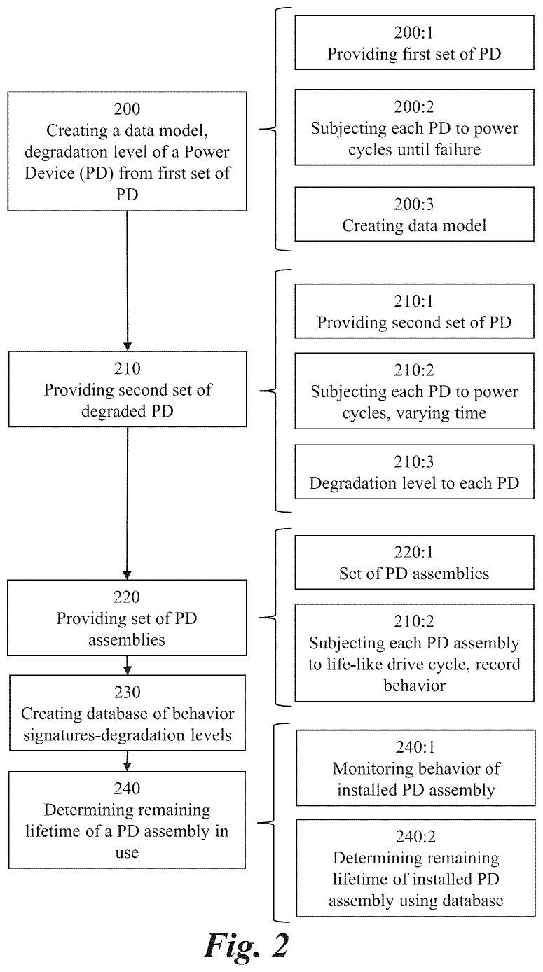

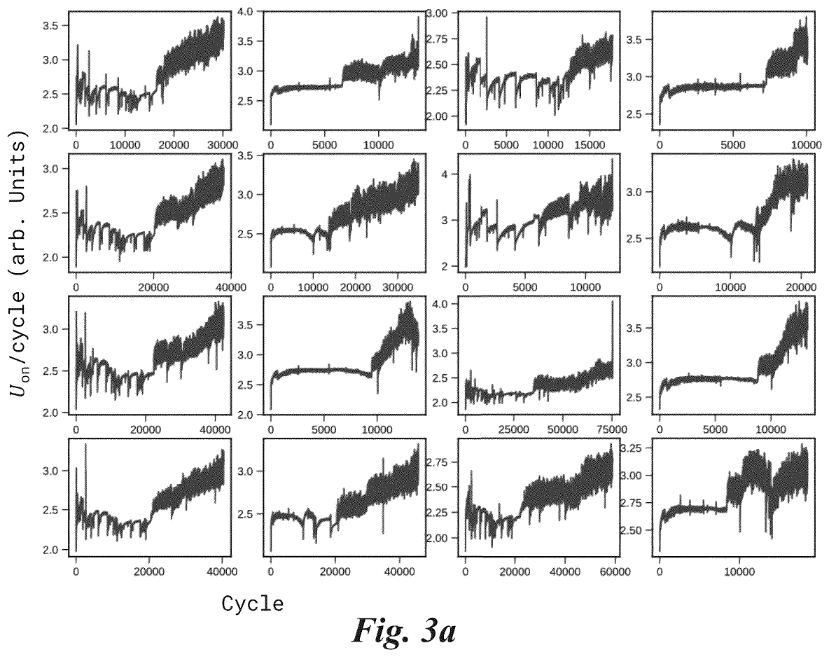

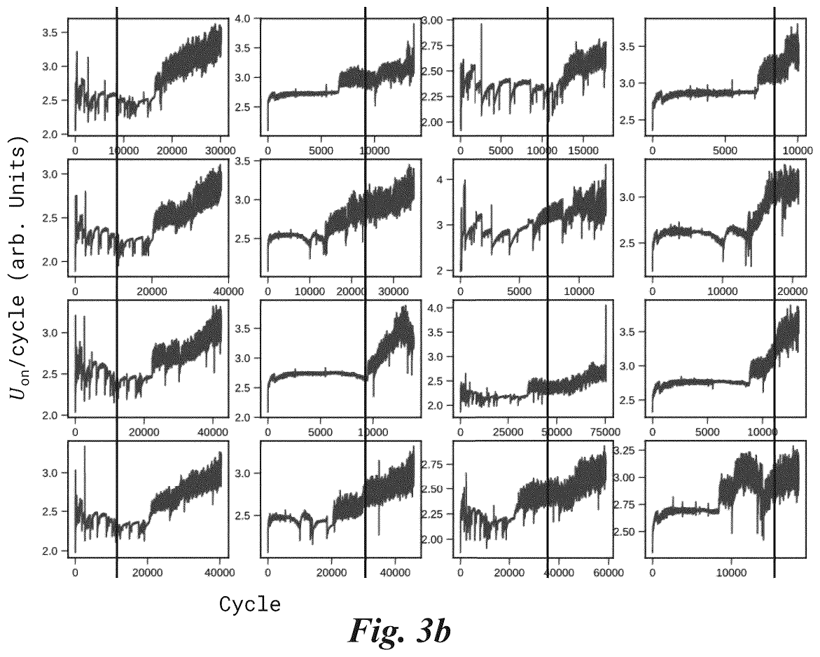

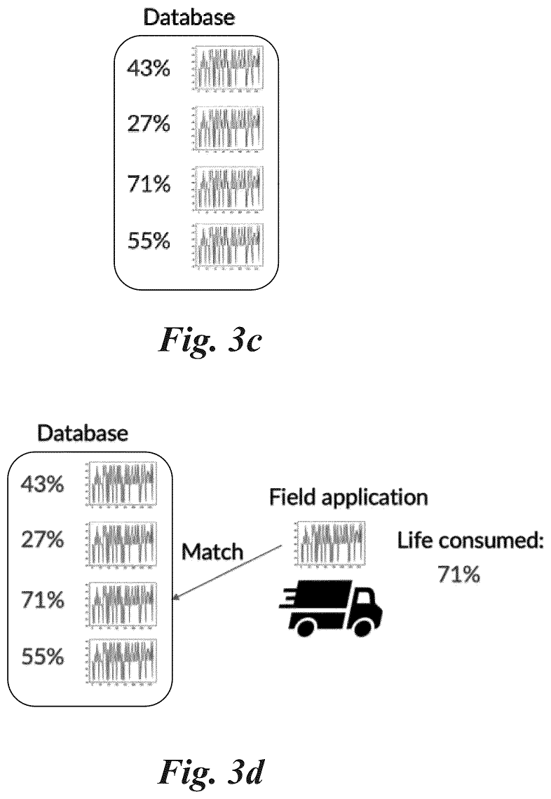

The method according to the invention method for prediction of degradation of a power device assembly is described with reference to the flowchart of FIG. 2, the illustrations of the output of different steps of the method of FIG. 3a-e and with reference to the system parts of FIG. 1a-c. The method the method comprises a pre-phase, a calibration phase and a run-time-phase. The pre-phase may be seen as a test-phase based on conventional accelerated life testing of power devices to provide a data model that is capable of ascribing o degradation level to an individual power device. In the calibration phase, which is a subsequent test-phase, test power devices 140 with different levels of degradation are produced. The power devices 140 with varying degradation level are used in a test set of power device assemblies which are subjected to life-like drive cycles and the behavior of the each individual power device assembly is recorded and used to build up a library of behavior data associated with one type of power devices 140. The calibration phase may be seen as calibrating the result of the accelerated life testing to a life like scenario. The run-time-phase may be seen as a field test, for example being part of a maintenance routine, of a power device assembly 140 in actual use in an application, for example in a vehicle.

In the method according to the invention the pre-phase comprises the main step of:
200:—Creating a data model relating a measured indicative parameter to a degradation level of a power device by performing accelerated life testing until failure on a first set of the specific power devices 110;

The calibration phase comprises the main steps of:
210:—Providing a second set of power devices with individual degradation levels by performing accelerated life testing under the same conditions as in the pre-phase. However, in this step the accelerated life testing is run with different duration for the individual test power devices and typically ending before failure of the power device. The data model is used to ascribe a degradation level to each individual test power device.
220:—Providing a set of a plurality of test power device assemblies, each comprising at least one test power device from the second set of test power devices, and subjecting each of the test power device assemblies to life-like testing and recording a behavior of each of the test power device assemblies during the life-like testing. The recorded behavior is ascribes as a behavior signature specific to the degradation level of the test power device, or power devices, comprised in each test power device assembly;
230—Creating a database of behavior signatures with associated degradation levels.

The run-time phase comprises the main step of:
240:—Determining the remaining lifetime of an installed power device assembly, the installed power device assembly corresponding to the test power device assemblies, by monitoring the behavior of the power device assembly and comparing the result with the behavior signatures of the database.

According to one embodiment the pre-phase of the method comprises the steps of:
200:1:—Providing a first set of a plurality of test power devices of the specific type of power device 110;
200:2:—Subjecting each of the test power devices in the first set of test power devices to power cycling and for each power device recording an indication parameter until failure for the power device. The step of subjecting test power devices is preferably performed with the first part of the system as schematically illustrated in FIG. 1a. Typical outputs, in this example the on-state voltage of a plurality of power devices 140 recorded per power cycle until failure is illustrated in FIG. 3a;
200:3:—Creating a data model using the recorded indication parameter for each test power device, the data model relating the indication parameter to an expected remaining life of the type of power device;

According to one embodiment the calibration phase comprises the steps of:
210:1:—Providing a second set of a plurality of test power devices of the specific type of power device 140.
210:2:—Subjecting each of the test power devices in the second set of test power devices to power cycling and recording the indication parameter and providing different duration of the power cycling for the individual test power devices. The duration of the power cycling for the individual test power devices should be arranged to cause various levels of degradation of the individual test power devices, however, not cause failure of the individual test power devices. Thereby, after the step, the second set second set of test power devices is a set of power devices 140 with different individual levels of degradation. The step of subjecting the second set of power devices preferably is performed with the first part of the system as schematically illustrated in FIG. 1a. Typical outputs, in this example the on-state voltage of a plurality of power devices 140 recorded per power cycle during different duration of the power cycling for the individual test power devices is illustrated in FIG. 3b, wherein the vertical lines indicates the power cycling being interrupted at different times.
210:3:—Ascribing a degradation level to each of the test power devices in the second set of test power devices using the data model. The degradation level is an indication of the remaining lifetime of the power device.
220:1—Providing a set of a plurality of test power device assemblies 140, each comprising at least one test power device 110 from the second set of test power devices Thereby, each individual power device assembly 140 can be assumed to have a specific and individual degradation level governed by the degradation level of the power device 110 comprised in the power device assembly 140. In the case that a power device assembly 140 comprises a plurality of power devices 110 with different degradation level, the degradation level of the power device assembly 140 may typically be governed by the power device 110 being most degraded.
220:2:—Subjecting each of the test power device assemblies to a predetermined life-like drive cycle and recording the behavior of each of the test power device assembly 140 during the drive cycle, and associating the recorded behavior as a behavior signature specific to the degradation level of the test power device comprised in each test power device assembly, and the step of subjecting the set of power device assemblies is preferably performed with the second part of the system as schematically illustrated in FIG. 1b. FIG. 3c schematically illustrates the database comprising behavior signatures with associated degradation levels.
230:1:—Creating a database of behavior signatures with associated degradation levels.

According to one embodiment the run-time-phase of the method comprises the steps of:
240:1:—monitoring an installed power device assembly 140 in use and recording the behavior of the installed power device assembly 140 during a predetermined time period. The step of monitoring the power device assemblies is preferably performed with the third part of the system as schematically illustrated in FIG. 1c;
240:2:—determining the remaining lifetime of the installed power device assembly 140 by using the database and comparing the recorded behavior of the power device assembly with the stored behavior signatures. FIG. 3d schematically illustrates comparing and matching the installed power device assembly 140 with behavior signatures stored in the database with associated degradation levels, thereby providing an estimate of the remaining lifeline of the installed power device assembly 140.

The terms “in use” and “installed power device assembly 140 in use” should be understood as the power device assembly 140 being mounted and operative in its intended use in a equipment, for example in an vehicle. The monitoring step 240:1 may be performed during the actual operation of the equipment or during testing of the equipment, for example following a maintenance protocol. In the latter, the equipment may not be in full operation, however, the parts involving the installed power device assembly should be. Both these scenarios are meant to be included in “in use” and “installed power device assembly 140 in use”.

The pre-phase and the calibration phase of the method may typically be performed once for each type of power device and/or each type of power device assembly. The run-time phase is typically repeated a number of times to test an installed power device assembly at different times during its expected lifetime and/or to test different installed power device assemblies of the same type.

The method may allow to adjust the database of behavior signatures with associated degradation values with real life data. If, for example, real life data shows that a type of power device assemblies degrades faster than expected from the behavior signatures the degradation level associated with a specific signature can be adjusted.

According to one embodiment of the invention the data model created in step 200 and utilized in step 210 is a machine learning model, ML. The step of creating a machine learning, ML, involves training the model with the first set of power devices 110. In the step of ascribing a degradation level to a power device the trained ML model is able to predict a level of degradation of a power device based on a recorded indicative parameter or physical measurement of the power device 110. Phrased differently, the ML model may be able to identify, or determine, a relationship, or a correlation, between a level of degradation of a power device and recorded indicative parameter of said power device. Suitable ML models may include deep learning approaches such as multilayer-perceptron, recurrent neural network, convolutional neural network and transformers.

According to one embodiment of the invention the data model created in step 200 and utilized in step 210 utilizes one of, or a combination of: support vector regression, linear regression, regression trees or autoregressive models

The step 240 of determining the remaining lifetime of the installed power device assembly may according to one embodiment involve determining the best match between the recorded behavior of the power device assembly with the stored behavior signatures, which could be performed with known methods for example, but not limited to using an Euclidean distance or a Fréchet distance. A further approach is to use a pattern matching technique or algorithm. Alternatively, the method may not seek the absolute best match, rather a match above a predetermined threshold may provide a sufficient measure of the degradation. It could also be envisaged determining that the level of degradation of the installed power device 140 equals a mean or a median of the stored behavior signatures.

In the step 220:2 of subjecting each of the test power device assemblies to a predetermined life-like drive cycle, the life-like drive cycle may preferably be-adapted to the specific type of component and its intended usage. The predetermined life-like drive cycle may be a simulation of a real-world application. The predetermined life-like drive cycle may be based on data from test vehicles that are operated in different test environments.

Thanks to the generation of the database with behavior signatures with associated degradation levels the step 240:1 of monitoring the installed power device assembly the predetermined time period may be short and still give a reliable result. According to one embodiment the predetermined time period is less than 5 seconds.

According to one embodiment the step 220:2 of subjecting the test power device assemblies to the predetermined life-like drive cycle has a duration in time for each test power device assembly that is equal to the predetermined time period of the step 240:1 of monitoring the power device assembly in use. Equal should here be understood as an aim to keep the time periods the same and a slight deviation, for example up to 10%, would not impair the result.

The power devices 110 may be any type of electronic or electrical device or component that is likely to be subjected to wear during use. According to one embodiment the power device 110 is a component used in power, or high-power electric or electronic devices. Typically, the power device 110 may be a semiconductor switching devices such as a diode, a thyristor or a power transistor. Power transistors include, but is not limited to, insulated-gate bipolar transistors, IGBTs, bipolar junctions transistors, BJTs, metal-oxide-semiconductor field-effect transistors, MOSFETs, junction-gate field-effect transistors, JFETs. In contrast to low power electronic systems concerned with the transmission and processing of signals and data, substantial amounts of electrical energy are processed in power electronics. In certain industrial applications the power range may go up to tens of megawatts. plurality of semiconductor power devices, or semiconductors. The semiconductors may thyristors and/or diodes.

The monitoring unit 120 may be arranged to monitor the indicative parameter of the power device by being connected to the power device 110, for example being electrically connected and detecting a voltage, or being thermally connected and detecting a temperature of the power device 110. Alternatively, the monitoring unit 120 may be arranged for contactless monitoring of an indicative parameter, for example infrared temperature measurement.

According to one embodiment the degradation level of an installed power device assembly 140 indicates a level of damage present in one or more connection interface(s) of a power device 110 comprised in the power device assembly. One or more connection interface(s) of the power device may comprise one or more wire bond(s) of the power device.

As apparent for the skilled person the remaining lifetime is directly derivable from the degradation level for a component or an assembly of components. In many applications it is preferred to present a value of the remaining lifetime to an operator or a maintenance engineer. Converting “degradation level” to “remaining lifetime” may for example involve comparing the total run-time of the equipment in which a power device assembly is a part and thereby get an estimate of expected remaining run-time for the equipment. Such estimates may comprise including predetermined safety margins before presenting any value of the remaining lifetime to for example an operator.

According to one aspect of the invention a database or library of behavior signatures with associated degradation levels is provided. According to that aspect a method comprising the pre-phase and the calibration phase as described above is provided.

All parts of the system 100a-c may be provided with various control and analyzing equipment which are well known in the art. According to one aspect of the invention, the parts of the system described with reference to FIGS. 1a-c are arranged to perform the steps of the above-described method and the various embodiments of the method.

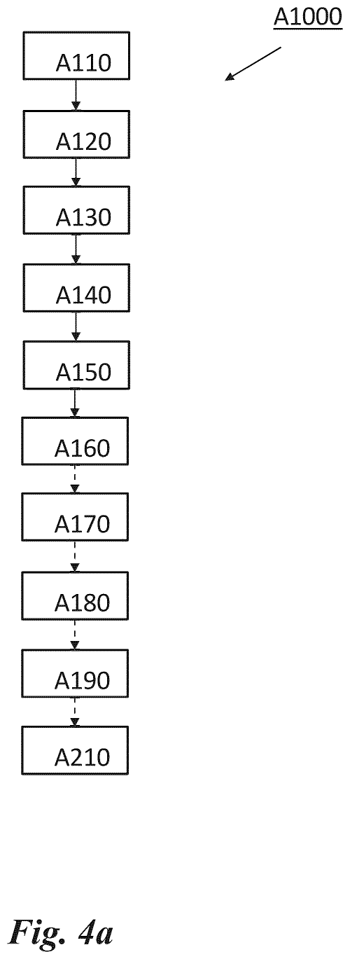

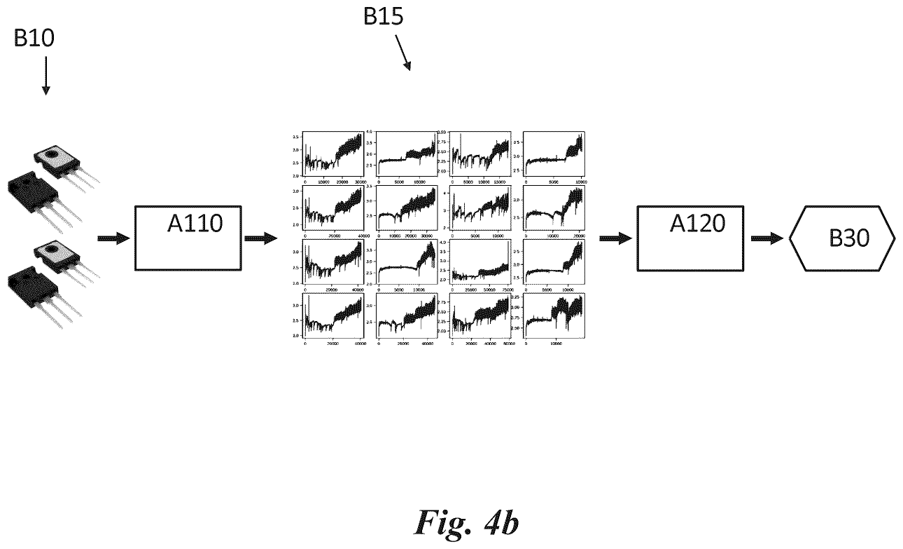

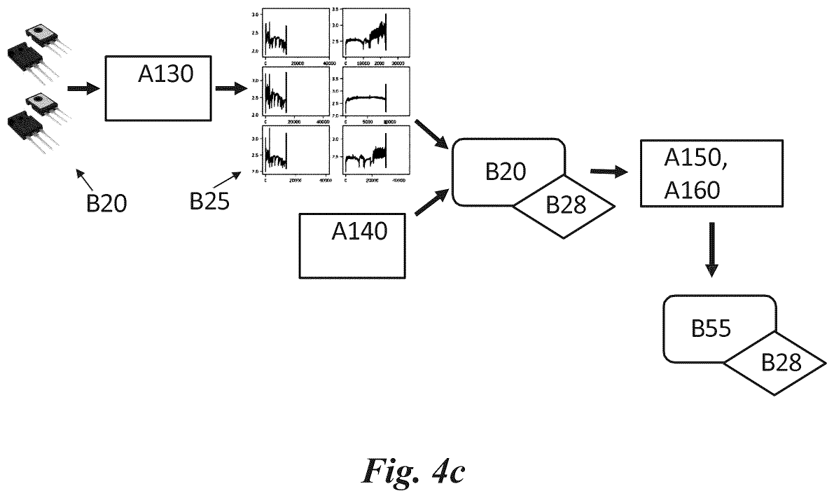

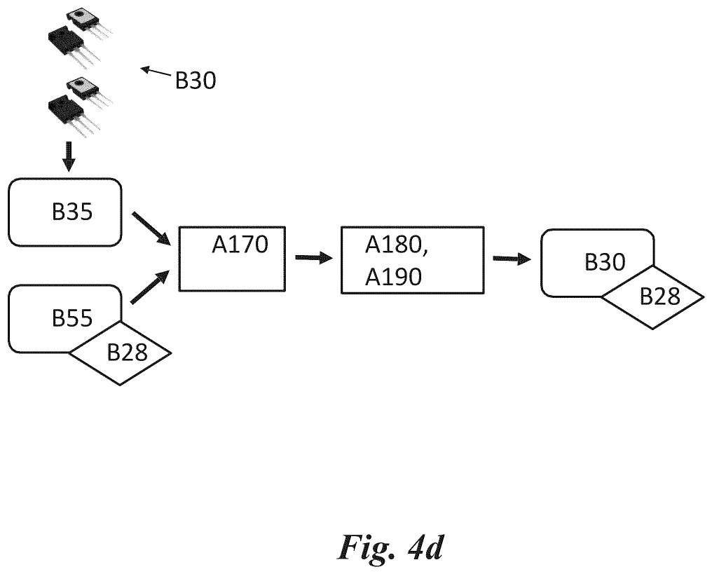

An exemplifying and non-limiting embodiment will be described with reference to FIGS. 4a-d. In this example the power device is a semiconductor high power transistor. The power device assembly 140 comprises of a single power device and the run-time phase is performed on a sample power device.

FIG. 4a schematically shows a method A1000 according to the embodiment. The method A1000 shown in FIG. 4a comprises the steps of performing A110 rounds of power cycling on each power device of a first plurality of power devices (not shown; see FIG. 4b), until failure of said power device, and recording a physical measurement (not shown; see FIG. 4b) of the respective power devices after each round of power cycling, creating A120 a machine learning, ML, model using the physical measurements (not shown; see FIG. 4b) recorded after each round of power cycling of said power devices as inputs, wherein the ML model is able to predict a level of degradation of a power device based on a recorded physical measurement of said power device. The method A1000 further comprises performing A130 a number of rounds of power cycling on each power device of a second plurality of power devices (not shown; see FIG. 4c), wherein the number of rounds is different for at least some of the second plurality of power devices, and recording an indicative parameter or physical measurement, in this case the on-state voltage (not shown; see FIG. 4c) of the respective power devices after each round of power cycling, thereby degrading the second plurality of power devices, applying A140 the ML model to the recorded physical measurements of each degraded power device of the second plurality of power devices in order to obtain a predicted level of degradation (not shown; see FIGS. 4b and 4c), subjecting A150 each degraded power devices of the second plurality of power devices to a predetermined drive cycle, and recording A160 behavior data (not shown; see FIGS. 4b and 4c) during the predetermined drive cycle for each degraded power device of the second plurality of power devices, and labeling the recorded behavior data with the predicted level of degradation of the degraded power device.

The method A1000 may further comprise comparing A170 a sample (not shown; see FIG. 4c) of behavior data of a sample power device, wherein said sample has been recorded in a real-world application in which the sample power device has been used, to the plurality of labeled behavior data, determining A180 a labeled behavior data of the plurality of behavior data which is the most similar to the sample of behavior data, and determining A190 that said sample power device has a level of degradation equal to the labeling of said predicted level of degradation which is most similar to the sample of behavior data.

Furthermore, the method A1000 may comprise determining A210 which labeled behavior data of the plurality of behavior data which has the highest measure of similarity.

FIG. 4b schematically shows a few steps of a method according to an exemplifying embodiment of the present disclosure. The method steps shown in FIG. 2 may be substantially equal to at least some of the steps of the method shown in FIG. 1, and therefore, reference is made to the description corresponding to FIG. 1.

FIG. 2 shows a plurality of first power devices B10, wherein four are shown in FIG. 2. The first power devices B10 may be understood as being new, as in unused. Each first power device B10 of first power devices B10 are put through rounds power cycling A110. After each round of power cycling A110 performed on a first power device B10, a physical measurement B15 is recorded. For each first power device B10, the process of performing A110 a round of power cycling and then recording a physical measurement B15 is repeated until failure of the first power device B10. The resulting output is then, for each first power device B10, a vector, a string and/or a curve of the recorded physical measurements B15, ordered from first to last. Thereby, output from the rounds of power cycling A110 is a number of physical measurement vectors B15, wherein the number is equal to the number of first power devices B10.

The output from the rounds of power cycling A110, i.e. the physical measurement vectors B15, is then fed as inputs into a machine learning algorithm in order to create A120 a machine learning model B40. The machine learning model B40 is configured to predict a level of degradation of a power device based on a received physical measurement vector, string or curve, which may be similar to the ones used as inputs to create the machine learning model B40.

FIG. 4c schematically shows a few steps of a method according to an exemplifying embodiment of the present disclosure. The method steps shown in FIG. 4c may be substantially equal to at least some of the steps of the method shown in FIG. 4a, and therefore, reference is made to the description corresponding to FIG. 4a. Further, the steps shown in FIG. 4c may use inputs, components and/or data from the steps shown in FIG. 4b, and therefore reference is also made to that figure and its corresponding description.

FIG. 4c shows a plurality of second power devices B20. The second power devices B20 may be identical to the first power devices B10 shown in FIG. 4b, except that they are not being used in the first rounds of power cycling A110, as shown in FIG. 4b and discussed in the description relating thereto. The second power devices B20 are being put through rounds power cycling A130, and similarly as for the power cycling A110 performed on the first power devices B10, a physical measurement B25 is being recorded after each round of power cycling A130. However, the difference between the rounds of power cycling A110 being performed on a first power device B10 and the rounds of power cycling A130 being performed on a second power device B20 is that the rounds of power cycling A130 being performed on a second power device B20 are interrupted after a randomly determined number of rounds. The result is a plurality of second power devices B20 that have been degraded to random degrees. Since the degradation is random, some of the second power devices B20 may be degraded to a similar and/or same degree. In FIG. 4c the recorded physical measurements B25 are shown as a plurality of graphs indicating physical measurements, and a respective line which symbolizes the (randomly determined) interruption of the rounds of power cycling A130.

The method further comprises using the machine learning model B30 (shown in FIG. 2) on the recorded physical measurements B25 in order to determine, or estimate, levels of degradation 28 for each second power device B20 based on the corresponding recorded physical measurements B25.

The second power devices B20, each having been labeled with a respective level of degradation B28, is then subjected A150 to a predetermined drive cycle, and during the predetermined drive cycle, behavior data B55 is being recorded for each second power device B20. Then, the behavior data B55 of a second power device B20 is labeled with the level of degradation of that second power device B20. Thereby, a library of labeled behavior data B55 is created.

FIG. 4d schematically shows a few steps of a method according to an exemplifying embodiment of the present disclosure. The method steps shown in FIG. 4d may be substantially equal to at least some of the steps of the method shown in FIG. 4a, and therefore, reference is made to the description corresponding to FIG. 4a. Further, the steps shown in FIG. 4c may use inputs, components and/or data from the steps shown in FIG. 4b and therefore reference is also made to those figure and their corresponding descriptions.

In FIG. 4d sample power devices B30 are shown. The sample power devices B30 have been used in a real world application, and are thereby degraded. By recording behavior data of a sample power device B30 when it is used in the real world application, a sample behavior data B35 is obtained. The method may then compare A170 the sample behavior data B35 to the library of labeled behavior data B55, B28 (as described in the description relating to FIGS. 4a and 4c). Further, the method may comprise determining A180 which labeled behavior data B55 that is the most similar, and that then determining A190 that the sample power device has a level of degradation B28 equal to the most similar labeled behavior data B55.

The person skilled in the art realizes that the present disclosure by no means is limited to the preferred embodiments described above. On the contrary, many modifications and variations are possible within the scope of the appended claims.

1. A method of determining the remaining lifetime of a power device assembly in use, the power device assembly comprising at least one power device of a specific type of power devices, the method comprising a pre-phase, the pre-phase comprising the main step:
creating a data model relating a measured indicative parameter to a degradation level of a power device by performing accelerated life testing until failure on a first set of the specific power devices,
a calibration phase comprising the main steps of:
providing a second set of power devices with individual degradation levels by performing accelerated life testing under the same conditions as in the pre-phase with different duration of the accelerated life testing for the individual test power devices, and using the data model to ascribe a degradation level to each individual test power device;
providing a set of a plurality of test power device assemblies, each comprising at least one test power device from the second set of test power devices, and subjecting each of the test power device assemblies to life-like testing and recording a behavior of each of the test power device assemblies during the life-like testing and associating the recorded behavior as a behavior signature specific to the degradation level of the test power device or devices comprised in each test power device assembly; and
creating a database of behavior signatures with associated degradation levels, and a run-time phase comprising the main step:
determining the remaining lifetime of an installed power device assembly, the installed power device assembly corresponding to the test power device assemblies, by monitoring the behavior of the power device assembly and comparing the result with the behavior signatures of the database.

2. The method according to claim 1, wherein the pre-phase comprises the steps of:
providing a first set of a plurality of test power devices of the specific type of power device;
subjecting each of the test power devices in the first set of test power devices to power cycling and for each power device recording an indication parameter until failure for the power device; and
creating a data model using the recorded indication parameter for each test power device, the data model relating the indication parameter to an expected remaining life of the type of power device,
the calibration phase comprises the steps of:
providing a second set of a plurality of test power devices of the specific type of power device;
subjecting each of the test power devices in the second set of test power devices to power cycling and recording the indication parameter and providing different duration of the power cycling for the individual test power devices;
ascribing a degradation value to each of the test power devices in the second set of test power devices using the data model, wherein the degradation value is an indication of the remaining lifetime of the power device;
providing a set of a plurality of test power device assemblies, each comprising at least one test power device from the second set of test power devices; and
subjecting each of the test power device assemblies to a predetermined life-like drive cycle and recording the behavior of each of the test power device assemblies during the drive cycle, and associating the recorded behavior as a behavior signature specific to the degradation value of the test power device comprised in each test power device assembly, and
creating a database of behavior signatures with associated degradation values, and
the run-time-phase comprises:
monitoring an installed power device assembly during use and recording the behavior of the power device assembly during a predetermined time period;
determining the remaining lifetime of the installed power device assembly by using the database and comparing the recorded behavior of the power device assembly with the stored behavior signatures.

3. The method according to claim 2, wherein the indication parameter is a measure of the on-state voltage of the individual power device.

4. The method according to claim 2, wherein the indication parameter is a measure of the temperature of the individual power device.

5. The method according to claim 2, wherein the indication parameter is a combination of measure of the on-state voltage and a measure of the temperature of the individual power device.

6. The method according to claim 1, wherein the data model is a machine learning model and the step of creating the data model comprises training the machine learning model.

7. The method according to claim 5, wherein the machine learning model utilizes one of or a combination of: multilayer-perceptron, recurrent neural network, convolutional neural network and transformers.

8. The method according to claim 1, wherein the step of determining the remaining lifetime comprises finding the best match between the recorded behavior of the power device assembly with the stored behavior signatures comprises using an Euclidean distance, a Féchet distance or a pattern matching technique.

9. The method according to claim 2, wherein the step of subjecting the test power device assemblies to the predetermined life-like drive cycle has a duration in time that is equal to the predetermined time period of the step of monitoring the power device assembly during use.

10. The method according to claim 9, wherein the predetermined time period is less than 5 seconds.

11. The method according to claim 1, wherein the degradation level of a power device assembly indicates a level of damage present in one or more connection interface(s) of a power device comprised in the power device assembly.

12. The method according to claim 11, wherein the one or more connection interface(s) of the power device comprises one or more wire bond(s) of the power device.

13. A system for determining the remaining lifetime of a power device assembly in use, the system comprising:
a first part comprising a power devices, a power cycling unit arranged to provide a drive cycle to the power device and monitoring unit is arranged to monitor an indicative parameter relating to the power device being subjected to a set of power cycles provided by the power cycling unit,
a second part comprising a power device assembly, the comprising of one or more power devices an assembly drive unit arranged to provide a life like drive cycle to the power device assembly and an assembly monitoring unit arranged to monitor and record behavior data of the power device assembly during the drive cycle; and
a third part comprising an installed power device assembly in use in an application, and a run-time monitoring unit connected to the installed power device assembly and arranged to monitor and record behavior data of the power device assembly during use.

14. The system according to claim 13, further comprising control means and analyzing means arrange to:
during a pre-phase control the first part of the system to perform the main step of:
creating a data model relating a measured indicative parameter to a degradation level of a power device by performing accelerated life testing until failure on a first set of the specific power devices,
during a calibration phase control the second part of the system to perform the main steps of:
subjecting each the test power device assembly in a set of a plurality of test power device assemblies, each comprising at least one test power device from the second set of test power devices, to life-like testing and recording a behavior of each of the test power device assemblies during the life-like testing and associating the recorded behavior as a behavior signature specific to the degradation level of the test power device or devices comprised in each test power device assembly;
providing a set of a plurality of test power device assemblies, each comprising at least one test power device from the second set of test power devices, and subjecting each of the test power device assemblies to life-like testing and recording a behavior of each of the test power device assemblies during the life-like testing and associating the recorded behavior as a behavior signature specific to the degradation level of the test power device or devices comprised in each test power device assembly; and
creating a database of behavior signatures with associated degradation levels, and
during a run-time phase control the third part of the system to perform the steps of:
determining the remaining lifetime of an installed power device assembly, the installed power device assembly corresponding to the test power device assemblies, by monitoring the behavior of the power device assembly and comparing the result with the behavior signatures of the database.

15. The system according to claim 13, further comprising control means and analyzing means arrange to:
during the pre-phase control the first part of the system to perform the steps of:
subjecting each of the test power devices in the first set of test power devices to power cycling and for each power device recording an indication parameter until failure for the power device; and
creating a data model using the recorded indication parameter for each test power device, the data model relating the indication parameter to an expected remaining life of the type of power device,
during the calibration phase control the second part of the system to perform the steps of:
subjecting each of the test power devices in the second set of test power devices to power cycling and recording the indication parameter and providing different duration of the power cycling for the individual test power devices;
ascribing a degradation value to each of the test power devices in the second set of test power devices using the data model, (wherein the degradation value is an indication of the remaining lifetime of the power device); and
subjecting each of the test power device assemblies in a set of a plurality of test power device assemblies to a predetermined life-like drive cycle, wherein each test power device assemblies comprises at least one test power device from the second set of test power devices and recording the behavior of each of the test power device assemblies during the drive cycle, and associating the recorded behavior as a behavior signature specific to the degradation value of the test power device comprised in each test power device assembly, and creating a database of behavior signatures with associated degradation values, and
during a run-time phase control the third part of the system to perform the steps of:
monitoring an installed power device assembly during use and recording the behavior of the power device assembly during a predetermined time period;
determining the remaining lifetime of the installed power device assembly by using the database and comparing the recorded behavior of the power device assembly with the stored behavior signatures.
